(19) United States
(12) Patent Application Publication
(10) Pub. No.: US 2007/0194446 A1
(43) Pub. Date: Aug. 23, 2007

(54) Memory module comprising an electronic printed circuit board and a plurality of semiconductor components and method

(76) Inventor: Hermann Ruckerbauer, Moos (DE)

Correspondence Address: SLATER & MATSIL LLP, 17950 PRESTON ROAD, SUITE 1000, DALLAS, TX, 75252, US

(21) Appl. No.: 11/657,387

(22) Filed: Jan. 24, 2007

(30) Foreign Application Priority Data
Jan. 24, 2006 (DE) 10 2006 003 376.0

(51) Int. Cl. H01L 23/48; H01L 23/52; H01L 29/40

(52) U.S. Cl. 257/734

(57) ABSTRACT

A memory module is proposed which has a first contact bank at a first edge of its electronic printed circuit board and a second contact bank at a second edge. The printed circuit board has first lines that reach from the first contact bank as far as input connections of at least some of the semiconductor components. The printed circuit board has second conductor lines that reach from output connections of at least some of the semiconductor components as far as the first contact bank. The printed circuit board has third conductor lines that reach from output connections of at least some of the semiconductor components as far as the second contact bank. The printed circuit board has fourth conductor lines that reach from the second contact bank as far as input connections of at least some of the semiconductor components.

This application claims priority to German Patent Application 10 2006 003 376.0, which was filed Jan. 24, 2006 and is incorporated herein by reference.

### TECHNICAL FIELD

The invention relates to a memory module comprising an electronic printed circuit board and comprising a plurality of semiconductor components.

### BACKGROUND

Memory modules of this type are often formed as DIMM (dual inline memory module), in which both main surfaces of the printed circuit board are populated with semiconductor components. The semiconductor components are BGAs (ball grid arrays), for example, which have a plurality of arrays of contact connections, inter alia with input connections and output connections. Each semiconductor component formed as a BGA or in some other manner has an integrated semiconductor chip with a semiconductor memory. The semiconductor chip is for example a volatile read/write memory, for example DRAM (dynamic random access memory). Often a plurality of housed semiconductor chips are in each case stacked one on top of another for space reasons and capacity reasons, so that each semiconductor component has a plurality of housed semiconductor components, a bottommost one of which is in each case mounted with its housing directly at the corresponding main surface of the printed circuit board.

Memory modules are inserted into slots or insertion openings of superordinate electronic units, for example of motherboards, and are then electrically driven by the superordinate electronic unit. Said electronic unit usually contains a memory controller or is connected to a memory controller. The memory controller serves for coordinating the data interchange with a plurality of memory modules.

In present-day motherboards and other electronic units, a plurality of memory modules are usually operated simultaneously, said memory modules in each case being inserted into corresponding slots. In this case, the main circuit board of the superordinate unit has a plurality of slots, wherein an arbitrary selection of said slots can be populated with a respective memory module, which is then identified during operation and is automatically driven. The number and the position of the inserted memory modules are nowadays identified automatically and the coordination of the data interchange is correspondingly controlled by the memory controller.

By virtue of the increasing storage capacity of the memory modules and the already high number of (for example approximately 280) contact connections per slot, the upper limit for the greatest possible parallelism in the data interchange with the memory modules has almost been reached. On account of the large number of semiconductor components per memory module, in part with a plurality of semiconductor chips stacked one above another per semiconductor component, and by virtue of the increasing storage capacity of the semiconductor chips themselves, the storage capacity (the amount of data that can be stored) of a memory module, but also indirectly the number of contact connections required per memory module are determined.

On the part of a motherboard or some other superordinate electronic unit, only a specific number of contact connections which, upon insertion of a memory module, in each case make contact with a contact connection of the contact bank of its printed circuit board can be provided per slot for a memory module. Said contact connections are usually lined up closely alongside one another on both main surfaces of the printed circuit board. The main circuit board of a motherboard or of some other superordinate electronic unit has a plurality of, for example, four or eight slots, wherein a memory module can be inserted into each slot.

By virtue of the increasing storage capacity of the memory modules, the capacity of the memory controller to process many data in parallel with one another is also encountering its limits. Since a memory controller is only designed for the parallel processing of a specific maximum number of data per clock cycle, for example of 64 parallel bits per clock cycle, a respective one of the memory modules can be accessed only with a specific bus width. Although the memory modules themselves could be provided with an even greater capacity, they can be driven on the part of the memory controller only with that bus width which the memory controller itself can process. Consequently, a memory controller that is present limits the bus width with which memory modules are accessed.

### SUMMARY OF THE INVENTION

In a first aspect, the present invention provides a memory module that enables more flexible interconnection and driving of a plurality of memory modules and which is able to drive further memory modules without the bus width for driving the memory modules having to be increased on the part of a memory controller. For example, embodiments of the invention provides a memory module that can drive further memory modules connected downstream without having to increase the number of contact connections of its contact bank by which the memory module itself is driven. Moreover, embodiments of the present invention, in the case of a plurality of memory modules connected up to one another, increase the memory address space that can be driven at maximum possible speed or clock rate, without disturbing load capacitances of the affected memory modules impairing the high-frequency signal interchange.

Further embodiments of the present invention provide a memory module that enables new possibilities for an extended data interchange between memory modules and a superordinate electronic unit. For example, embodiments of the present invention provide a memory module that can be connected to a superordinate electronic unit and can itself, for its part, drive a further memory module. This driving of a further memory module via a memory module according to embodiments of the invention is intended, in particular, not to require any increased parallelism of the data interchange with a superordinate electronic unit or the memory controller thereof. Furthermore, embodiments of the present invention provide a further memory module that can be driven via a memory module described above without being driven directly by a superordinate electronic unit. Other embodiments of the present invention provide a connecting means for connecting two such memory modules. In addition, the other embodiments of the invention provide an electronic arrangement comprising at least two memory modules, only one of which is driven directly by a superordinate electronic unit, and also to provide a method by which a plurality of memory modules can be operated with more flexibly than hitherto possible.

In one embodiment, a memory module includes an electronic printed circuit board and a plurality of semiconductor components. The printed circuit board has at least one main surface and also a first and a second edge. The semiconductor components are arranged on the at least one main surface of the printed circuit board. The printed circuit board has on the at least one main surface, a first contact bank, which is arranged at the first edge of the printed circuit board, and also a second contact bank, which is arranged at the second edge of the printed circuit board. The contact banks in each case have a multiplicity of contact connections. The printed circuit board has first lines that reach from the first contact bank as far as input connections of at least some of the semiconductor components. The printed circuit board has second conductor tracks that reach from output connections of at least some of the semiconductor components as far as the first contact bank. The printed circuit board has third conductor tracks that reach from output connections of at least some of the semiconductor components as far as the second contact bank. The printed circuit board has fourth conductor tracks that reach from the second contact bank as far as input connections of at least some of the semiconductor components.

Embodiments of the invention provide a memory module that in each case has a contact bank not only at a first edge of one or two main surfaces but at two different edges and which is therefore suitable for being connected not only to a superordinate electronic unit but also to a further electronic component, for example a further memory module or an interposed connecting means. The memory module according to embodiments of the invention is constituted, in particular, such that it not only communicates with the superordinate electronic unit via the contact bank arranged at one edge, but can likewise communicate with one or a plurality of further memory modules via the contact bank arranged at the other edge. For this purpose, two contact banks each having a multiplicity of electrical contact connections are preferably provided at two mutually opposite edges of the printed circuit board of the memory module according to embodiments of the invention. The communication with a motherboard or some other superordinate electronic unit can be conducted with the contact bank arranged at the first edge, whereas the communication with one or a plurality of further memory modules is effected via the contact bank arranged at the second edge.

The memory module according to embodiments of the invention has first lines that reach proceeding from the first contact bank arranged at the first edge as far as input connections of at least some of the semiconductor components of the memory module. These lines are also provided in conventional memory modules; according to embodiments of the invention, however, they can also be used to forward data intended for other memory modules in order to drive one or a plurality of memory modules connected downstream. The memory module according to embodiments of the invention furthermore has second lines that reach proceeding from output connections of at least some of the semiconductor components to the first contact bank. The second lines, too, are preferably formed as in conventional memory modules. However, in the memory module according to embodiments of the invention, they can also be used to forward signals that have been received from a second contact bank arranged at a second edge as far as the first contact bank. The second lines are, in particular, also intended for forwarding signals of one or a plurality of further memory modules connected downstream, in particular in the direction of a superordinate electronic unit.

The memory module according to embodiments of the invention furthermore has third lines that reach proceeding from output connections of some semiconductor components as far as the second contact bank. They therefore produce a connection between the second contact bank and the output connections of all or some of the semiconductor components of the memory module according to embodiments of the invention. They can be used, in particular, for control commands, address commands and data to be stored which are firstly transferred through the semiconductor components of the memory module according to embodiments of the invention, but are to be processed or to be stored in one or a plurality of further memory modules connected downstream.

Finally, the memory module according to embodiments of the invention also has fourth conductor tracks that reach proceeding from the second contact bank as far as input connections of at least some of the semiconductor components. The fourth lines serve, in particular, to conduct data received from one or a plurality of memory modules connected downstream, in particular data values that have been read out, as far as the semiconductor components of the memory module according to embodiments of the invention. The data can then be transferred through the semiconductor components of the semiconductor module according to embodiments of the invention and be forwarded via the second lines further to the first contact bank and then to a structurally superordinate electronic unit.

The memory module according to embodiments of the invention therefore additionally contains, with respect to a conventional memory module, a second contact bank arranged at a second edge of the printed circuit board, and also the third conductor tracks and the fourth conductor tracks. As a result, the memory module according to embodiments of the invention can be used not only as a storage medium but also as an interface to one or a plurality of memory modules connected downstream, with the result that more than one memory module can be driven with a slot conventionally provided for only a single memory module. In particular, with the bus width unchanged, both the memory module according to embodiments of the invention and at least one further memory module connected downstream can be driven via the same slot. The number of electrical contacts of the slot does not need to be increased for this purpose. Primarily, however, the memory module according to embodiments of the invention, which is able to concomitantly drive one or a plurality of memory modules connected downstream, manages without additional contact connections of the first contact bank for the memory modules connected downstream. The second contact bank does not require more contact connections than the contact bank of a conventional memory module. Both are possible because the first signals, intended for the memory modules connected downstream, are communicated via the first (and third) conductor tracks, the first lines being necessary anyway for the operation of the memory module in order, for instance, to supply the semiconductor components thereof with control signals, address signals and data values to be stored. By virtue of the forwarding of said first signals through third conductor tracks, which only have to be provided in the same number as the first lines, the second contact bank requires at most the same number of contact connections as the first contact bank.

Analogously, both the data values read out from the memory module itself and the data values read out from the memory modules connected downstream can be communicated via the second (and fourth) conductor tracks, with the result that a higher number of contact connections per contact bank than in a conventional memory module is also not necessary for the data values read out. In particular the loop back interconnection made possible by the memory module according to embodiments of the invention, in which interconnection of the fourth conductor tracks communicate the read-out data values of memory modules connected downstream from the second contact bank to input connections of the semiconductor components of the memory module according to embodiments of the invention, in order to subsequently send them back to the first contact bank again through the second conductor tracks, obviates the need to increase the number and packaging density of the contact connections per contact bank.

By means of the memory module according to embodiments of the invention, the memory address space of all the memory modules connected downstream of one another can be driven at the maximum possible speed or clock rate on the part of the memory controller (or a superordinate electronic unit), without disturbing load capacitances of the affected memory modules impairing the high-frequency signal interchange. This is because the series connection according to embodiments of the invention of a plurality of memory modules enables the control commands, address commands and data values to be interchanged at the same speed that is conventionally possible when accessing a single memory module. A reduction of the transfer speed owing to possible connection in parallel of a plurality of memory modules that are to be driven simultaneously is not necessary.

It is preferably provided that the plurality of semiconductor components has a first group of semiconductor components and a second group of semiconductor components, wherein the first and the fourth lines are connected to input connections of semiconductor components of the first group, and wherein the second and third lines are connected to output connections of the semiconductor components of the second group. The semiconductor components of a group are in each case driven in parallel with one another, at least those of them that are arranged on different area regions of one or two main surfaces of the printed circuit board of the memory module according to embodiments of the invention. By contrast, the semiconductor components of two or of more than two groups of semiconductor components are preferably connected in series with one another on the memory module. However, they may likewise be connected up in parallel with one another in accordance with fly by technology and only be arranged along one and the same group of conductor tracks. Fourth lines that proceed from contacts of the second contact bank and are connected to contact connections of the first contact bank are provided in both cases, however. The fourth lines may be connected to the second lines of the memory module according to embodiments of the invention, for example, via the semiconductor components or via lines that lead through between the semiconductor components arranged on both sides of the printed circuit board.

It is preferably provided that at least some of the semiconductor components of the first group are driven in parallel with one another, that at least some of the semiconductor components of the second group are likewise driven in parallel with one another, and that the semiconductor components of the first group are connected in series with the semiconductor components of the second group.

It is preferably provided that the semiconductor components of the first group are connected in series with the semiconductor components of the second group in such a way that at least some electrical signals which are communicated by the first and/or fourth lines to the semiconductor components of the first group are forwarded through the semiconductor components of the first group at least as far as the semiconductor components of the second group. This embodiment is based on a series connection of the semiconductor components of a plurality of groups in which communicated signals, in particular data to be stored, and control commands and also address commands are transferred successively through a plurality of semiconductor components until they reach that semiconductor component in which they are to be processed or to be stored.

It is preferably provided that the semiconductor components of the first group are connected in series with the semiconductor components of the second group in such a way that electrical signals that are conducted from output connections of the semiconductor components of the first group to semiconductor components of the second group are forwarded through the semiconductor components of the second group as far as the second and/or third lines. In particular, it is provided that electrical signals forwarded via the fourth lines are forwarded to the second lines.

It is preferably provided that the memory module can be connected directly to a superordinate electronic unit by means of the first contact bank and can be connected up to at least one further memory module by means of the second contact bank in such a way that the at least one further memory module is driven by the memory module according to embodiments of the invention. Consequently, the further memory module receives all signals required for operation, in particular the control commands, address commands and the data values to be stored, via the detour of the memory module according to embodiments of the invention. Consequently, the memory module according to embodiments of the invention can be interposed between a further memory module and a superordinate electronic unit. Data that have been read out or are to be read out from the at least one further memory module can also be forwarded to the superordinate electronic unit via the memory module according to embodiments of the invention.

It is preferably provided that the third lines of the printed circuit board of the memory module lead to contacts of the second contact bank which are intended for forwarding signals to at least one further memory module. The third lines of the memory module according to embodiments of the invention can be connected directly or indirectly to the first lines of the memory module.

It is preferably provided that the fourth lines of the memory module are connected to contact connections of the second contact bank which are intended for receiving signals of at least one further memory module. The fourth lines serve, in particular, for forwarding data values that have been read out or are to be read out from one or a plurality of memory modules connected downstream. The fourth lines can be connected directly or indirectly to the second lines of the memory module according to embodiments of the invention. Compared with a conventional memory module, the fourth lines represent extensions or continued line portions of the second lines that reach as far as further contact connections of the second contact bank.

It is preferably provided that the memory module is constituted such that the second lines forward to the first contact bank both signals read out from the semiconductor components of the memory module and those signals which are received with the aid of the second contact bank and forwarded through the fourth lines. Consequently, with the aid of the second lines, it is possible to forward not only the signals assigned to the semiconductor components of the memory module according to embodiments of the invention to the superordinate electronic unit, but likewise also the signals received from one or a plurality of memory modules connected downstream.

It is preferably provided that the memory module is constituted such that the first lines forward both signals intended for processing in semiconductor components of the memory module and signals that are to be forwarded as far as the second contact bank, wherein the signals that are to be forwarded as far as the second contact bank are forwarded to contact connections of the second contact bank via the third lines. Consequently, the first lines can be used to forward commands or data that are intended both for the memory module according to embodiments of the invention and for one or a plurality of memory modules connected downstream. A command or a data value that is intended for a memory module connected downstream is only forwarded through the memory module according to embodiments of the invention that is processed, namely executed or stored, only in the memory module connected downstream.

It is preferably provided that the third lines comprise control lines, address lines and data lines for data to be written. The third lines may be formed in the same way as the first lines.

It is preferably provided that the fourth lines comprise data lines for data that are to be read out and/or have been read out. The fourth lines are formed, in particular, in the same way as the second lines. They may, in particular, have the same bus width, a similar line cross section and correspondingly identically chosen other parameters and be formed from the same materials.

It is preferably provided that the third and the fourth lines furthermore in each case comprise clock signal lines that communicate a clock signal. Consequently, for each group of third and fourth lines, in each case a dedicated clock signal line or a corresponding pair of complementary clock signal lines is provided, which provides a respective clock signal in the form of two lines whose potential difference produces a clock signal that is variable twice per clock cycle.

It is preferably provided that the first and the second edge run along a first direction, and that the at least one main surface extends between the first and the second edge. In this case, both contact banks are arranged at edges of the printed circuit board that are arranged opposite to one another. As an alternative, in particular in the case of an approximately square printed circuit board, the two contact banks may be arranged for instance at two mutually adjacent edges.

In another embodiment, the invention furthermore achieved by means of a further memory module comprising an electronic printed circuit board and a plurality of semiconductor components. The printed circuit board has at least one main surface and also a first and an opposite second edge. The first and the second edge run along a first direction, and wherein the at least one main surface extends between the first and the second edge. The printed circuit board can be mounted both at the first edge and at the second edge at a superordinate electronic unit and has a contact bank at the first edge.

Although this further memory module according to this embodiment of the invention has, like a conventional memory module, a contact bank only at one edge of the printed circuit board (on one or on both main surfaces of the printed circuit board), which contact bank is connected up to the semiconductor components via electrical lines, according to embodiments of the invention the second edge is formed such that there the memory module, on account of its geometric dimensions, can be securely inserted into a slot of a superordinate electronic unit and can be connected only mechanically, but not electrically to the superordinate electronic unit. Consequently, this mechanical connection at the second edge of the printed circuit board does not serve for the electrical driving of this further memory module according to embodiments of the invention, but only for mechanical fixing; the electrical driving is furthermore effected by the contact bank arranged at the first edge. Consequently, this second memory module according to embodiments of the invention can be operated in a superordinate electronic unit such that it is fixed at the superordinate electronic unit not with its contact bank but rather with the second edge, and receives the signals required for operation and for data interchange through a further memory module or a suitable connecting means, i.e. an intermediate adapter, instead of via the electronic unit. Accordingly, it is provided that this further memory module can be mounted at its second edge at a superordinate electronic unit without the memory module being driven from its second edge directly by the superordinate electronic unit.

It is preferably provided that the memory module is constituted such that it can be driven via the contact bank at the first edge of the printed circuit board optionally either directly by a superordinate electronic unit or via another memory module. Consequently, the contact bank is formed in the same way as the contact bank of a conventional memory module; it can, in particular, be inserted directly into a slot of a motherboard or some other superordinate electronic unit. In addition, the memory module according to embodiments of the invention can also be inserted or pushed into a conventional slot with its second edge, at which no contact bank is provided. Accordingly, it is provided, in particular, that the memory module can be driven via the contact bank at the first edge of the printed circuit board optionally either directly by the superordinate electronic unit or by a memory module according to embodiments of the invention with two contact banks arranged at opposite edges.

It is preferably provided that the further memory module has a contact bank only at its first edge, first and second lines being connected to contact connections of said contact bank. The first lines reach from contacts of the contact bank as far as input connections of at least some of the semiconductor components. The second lines reach from output connections of at least some further semiconductor components as far as further contacts of the contact bank.

The semiconductor components of the further memory module according to embodiments of the invention are thus connected by the first lines on the input side and by the second lines on the output side to corresponding contacts of the contact bank at the first edge of the printed circuit board. This further memory module is suited to being driven as a memory module connected downstream only indirectly by a superordinate electronic unit. This memory module has a contact bank only at one edge; the opposite second edge is intended only for mechanical fixing at a slot of the superordinate electronic unit and is therefore configured geometrically in a suitable manner. No such electrical contact connections that would be conductively connected to the semiconductor components are provided at the second edge, however. Moreover, this further memory module does not contain third or fourth lines which would lead toward the second edge.

A description is given below of further preferred embodiments which can apply equally to the memory module according to embodiments of the invention that was described first and also to the further memory module to be connected downstream.

It is preferably provided that the printed circuit board of the respective memory module has two main surfaces which are remote from one another and which are both populated with semiconductor components. As an alternative, only one main surface of the printed circuit board may be populated with semiconductor components.

It is preferably provided that each contact bank of the printed circuit board has in each case a plurality of contact connections on both main surfaces of the printed circuit board. As an alternative, particularly in the case of a memory module populated with semiconductor components only on one side, the contact bank at the relevant first and/or second edge may have contact connections for example on only one main surface.

It is preferably provided that the first lines comprise control lines, address lines and data lines for data to be written to the semiconductor components. It is furthermore preferably provided that the second lines comprise data lines for data to be read out from the semiconductor components.

It is preferably provided that the first and the second lines furthermore in each case comprise clock signal lines that communicate a clock signal. It is therefore possible to provide for example a plurality of first lines, of which some lines are control lines, others are in turn address lines and still others are in turn data lines for data values to be stored. Still further lines from among the first lines are clock signal lines and communicate a clock signal temporally synchronously and in an undelayed manner with respect to the control commands, address commands and data values. All control lines, address lines, data lines and clock signal lines may be formed as line pairs, each line pair transmitting a respective data bit and the corresponding digital data value “0” or “1” being predefined by the potential difference between the two lines of a line pair. This results in an increased data stability of the communicated signals and furthermore enables reliable operation at even higher clock frequencies. Furthermore, the second lines may also comprise, apart from data lines for data to be read out, dedicated separate clock signal lines which communicate a clock signal in an undelayed manner temporally synchronously with data values to be read out.

It is preferably provided that the first lines have branching nodes at which the first lines branch toward a plurality of semiconductor components of the memory module that are to be driven in parallel with one another. Consequently, a plurality of semiconductor components can be driven in parallel with one another on the memory module, to be precise independently of whether the memory module is driven directly by a superordinate electronic unit or itself drives a memory module connected downstream.

It is preferably provided that proceeding from the branching nodes, the first lines lead to the semiconductor components of the first group. The groups of semiconductor components may correspond to the subdivision of the semiconductor components that can be mounted on a memory module into so-called “ranks”, so that, by way of example, the first and second groups of semiconductor components correspond to a first and a second rank of a memory module. However, the assignment in groups may also be performed in some other way.

It is preferably provided that the semiconductor components in each case comprise housed semiconductor chips whose chip housings have input connections and output connections mounted on the printed circuit board. The chip housings may be formed in particular as ball grid arrays.

It may be provided that the semiconductor components in each case have a plurality of housed semiconductor chips which are stacked one above another and a bottommost housed semiconductor chip of which in each case is mounted with a housing at the printed circuit board.

Furthermore, it may be provided that the semiconductor chips comprise dynamic read/write memories, for example random access memories such as DRAMs. However, other volatile or else nonvolatile semiconductor memories may also be provided in the semiconductor components.

It is preferably provided that the respective memory module has at least two groups of semiconductor components, wherein each group comprises a plurality of semiconductor components driven in parallel with one another, and wherein the semiconductor components of one group are in each case connected in series with the semiconductor components of the other group.

The object on which embodiments of the invention is based is furthermore achieved by a connecting means for electrically connecting two memory modules to one another, wherein the connecting means has a first and a second connection device, to which a memory module can in each case be connected directly, wherein the first and the second connection device in each case has a multiplicity of electrical contacts, and wherein a plurality of contact connections of the first connection device are connected to a plurality of contacts of the second connection device. For this purpose, the connecting means may have, in particular, electrical lines that lead from the contact connections of the first connection device to those contact connections of the second connection device. The lines are connected to the contacts of the first and second connection devices in such a way that a memory module connected to the second connection device can be connected with the aid of the connecting means to a memory module which is provided with two opposite contact banks and from which it is driven electrically. The first and second connection devices may in each case be formed in the same way as a slot of a superordinate electronic unit into which a memory module is usually inserted if it is connected to the superordinate electronic unit (for example, a motherboard).

It is preferably provided that the first and the second connection devices are constituted such that an electronic printed circuit board of a memory module can in each case be inserted or plugged into the respective connection device.

It is preferably provided that the first and the second connection device are constituted such that a printed circuit board of a memory module which has a contact bank with a multiplicity of electrical contact connections at an edge can in each case be connected to the respective connection device in such a way that the contact connections of the contact bank of the printed circuit board make contact with the electrical contacts of the respective connection device of the connecting means. Consequently, the connecting means makes contact in each case with the contact connections of a contact bank of the relevant memory module with the aid of the contacts of both connection devices (or slots).

It is preferably provided that the connecting means is constituted such that a memory module which has two contact banks remote from one another at opposite edges and which furthermore has the first to fourth lines which can be connected via the connecting means to a further conventional memory module or a further memory module according to embodiments of the invention provided with a second edge suitable for insertion. With the aid of the connecting means according to embodiments of the invention, one or a plurality of memory modules connected downstream can thus be driven by a memory module which in each case has a contact bank at two opposite edges of its main surfaces. Each contact bank of the memory modules may optionally be formed on one or on both main surfaces of the printed circuit board, that is to say be a one-sided or two-sided contact bank.

It is preferably provided that the first and the second connection device of the connecting means are oriented such that the connecting means can be simultaneously pushed or plugged onto two memory modules, the printed circuit boards of which in each case face the connecting means with an edge. In particular, the connecting means according to embodiments of the invention constitutes a U-shaped bridge which can be pushed or plugged onto two memory modules inserted one alongside another in a superordinate unit.

In another embodiment, the invention provides an electronic arrangement having at least one first memory module, at least one second memory module, a connecting means and a superordinate electronic unit, by which the memory modules are driven. The superordinate electronic unit has a first and a second connection device, at which one of the memory modules can in each case be mounted. The first memory module is mounted with its first edge at the first connection device of the superordinate electronic unit and with its second edge at the first connection device of the connecting means. The second memory module is mounted with its first edge at the second connection device of the connecting means and with its second edge at the second connection device of the superordinate electronic unit.

It is preferably provided that the first memory module of the arrangement is electrically driven by the first connection device of the superordinate electronic unit, and that the second memory module is mechanically fixed with its second edge at the second connection device of the superordinate electronic unit without being electrically driven via said second connection device. Consequently, only the first memory module is driven directly via the superordinate electronic unit. The second memory module is only driven indirectly, namely via the first memory module and the connecting means plugged onto both semiconductor modules. It is accordingly provided that the second memory module is electrically driven by the superordinate electronic unit via the first memory module and the connecting means.

It is preferably provided that at least the second connection device of the connecting means and the first and the second connection device of the superordinate electronic unit are formed in the same way, with the result that the second memory module could optionally be connected to one of said three connection devices with its contact bank arranged at the first edge. Thus, the second memory module, unless it is driven precisely via the first memory module and the connecting means, can also be inserted with its contact bank directly into the first or second connection device of the superordinate electronic unit and then be driven directly. However, this requires, for each occupied slot, in each case additional capacity of the memory controller with regard to the amount of data that can be transferred in parallel with one another. This disadvantage does not apply if, as in the claimed arrangement, the second memory module is inserted upside down, that is to say with its second edge, into the superordinate electronic unit and is driven via the first memory module.

It is preferably provided that the superordinate electronic unit has a main circuit board, wherein a plurality of memory modules can be fitted to the main circuit board and can be electrically driven via the main circuit board. By way of example, four or eight slots may be provided for a plurality of memory modules. Depending on the population of a different number of slots, the individual memory modules can be driven in parallel with one another with a variable bus width. With the bus width unchanged, more memory modules than conventionally can be driven with the aid of the electronic arrangement according to embodiments of the invention, without having to increase the number of signals (control signals, address signals, data values to be stored and data values to be read out) that can be communicated simultaneously on the part of the memory controller.

It is preferably provided that the connecting means connects the third lines of the first memory module to the first lines of the second memory module and connects the fourth lines of the first memory module to the second lines of the second memory module. In particular a loop back configuration of a plurality of memory modules connected downstream of one another is thereby realized in a simple manner.

In another embodiment, the invention provides a method for operating at least one first and one second memory module, wherein the first and the second memory module in each case have an electronic printed circuit board and a plurality of semiconductor components. The printed circuit board of the first and of the second memory module in each case have first and second lines. The first lines are connected to input connections of at least some of the semiconductor components of the respective memory module. The second lines are connected to output connections of at least some of the semiconductor components of the respective memory module. The first and the second memory module are operated in such a way that clock signals and also other, first signals are forwarded via the first lines and the semiconductor components of the first memory module to the second memory module and are processed in the second memory module.

It is preferably provided that the first signals are forwarded to the second memory module via third lines of the first memory module, which are connected to output connections of at least some of the semiconductor components of the first memory module. Said first signals, preferably control commands, address commands and data values to be stored and/or a clock signal, thus successively pass through the first and third lines of the first memory module.

It is preferably provided that the first and the second memory module are operated in such a way that second signals are forwarded via the second lines of the second memory module to the first memory module. Data read out from the second memory module are thus forwarded to a superordinate unit via the first memory module.

In particular, it is provided that the second signals are forwarded in the first memory module to the second lines of the first memory module. In particular, it is provided that the second signals are forwarded to the second lines of the first memory module via the fourth lines of the first memory module. As a result, the second signals are conducted as far as the first contact bank of the first memory module. The data values to be read out of the second memory module or the second signals are generally also transferred through the semiconductor components of the first memory module after they have passed through the fourth lines and before they reach the second lines.

It is preferably provided that both signals that drive the first memory module and those signals that drive the second memory module are forwarded via the first lines of the first memory module. The signals intended for driving the first memory module itself can be communicated in multiplex/demultiplex operation with those signals which drive one or a plurality of memory modules connected downstream. On the part of the memory controller, only a suitably formed evaluation unit or signal communicating unit for signals to be transmitted to the memory modules and the received data values is required in order to operate a plurality of memory modules connected downstream of one another in the “loop back” mode via one and the same slot of the superordinate electronic unit. In this case, the order of the assignment of read-out data values to the respective memory modules is different for the first signals and for the second signals. By way of example, given an arrangement of n successively connected memory modules, the first signals can be communicated in cyclic order according to an ascending module number 1, 2, 3, . . . , n, whereas the data values read out are communicated in a different order with regard to the module number of the assigned memory module, for example in the reverse order of descending module number n, . . . , 3, 2, 1. The interconnection of the memory modules connected downstream of one another in the “loop back” mode has the advantage that additional contact connections of the two contact banks of the memory module according to embodiments of the invention are unnecessary for the driving of the memory modules connected downstream.

It is preferably provided that both signals that are assigned to the first memory module and those signals that are assigned to the second memory module are forwarded via the second lines of the first memory module.

It is preferably provided that the first signals comprise control commands, address commands and data values to be stored. Furthermore, it is preferably provided that the second signals comprise data that have been read out.

Preferably, at least one first memory module and at least one second memory module are operated with the aid of the method according to embodiments of the invention. The second memory module is then electrically driven via the interposed first memory module. In particular, at least one first and at least one second memory module of an electronic arrangement are operated with the aid of the method according to embodiments of the invention.

### DESCRIPTION OF THE DRAWINGS

Embodiments of the invention are described below with reference to the figures, in which:

FIG. 1 shows a schematic plan view of a memory module and a further memory module according to a first embodiment of the invention;

FIG. 2 shows a schematic cross-sectional view of an arrangement comprising both memory modules from FIG. 1; and

FIG. 3 shows a schematic cross-sectional view of two embodiments of a semiconductor component for the memory modules.

### DETAILED DESCRIPTION OF ILLUSTRATIVE EMBODIMENTS

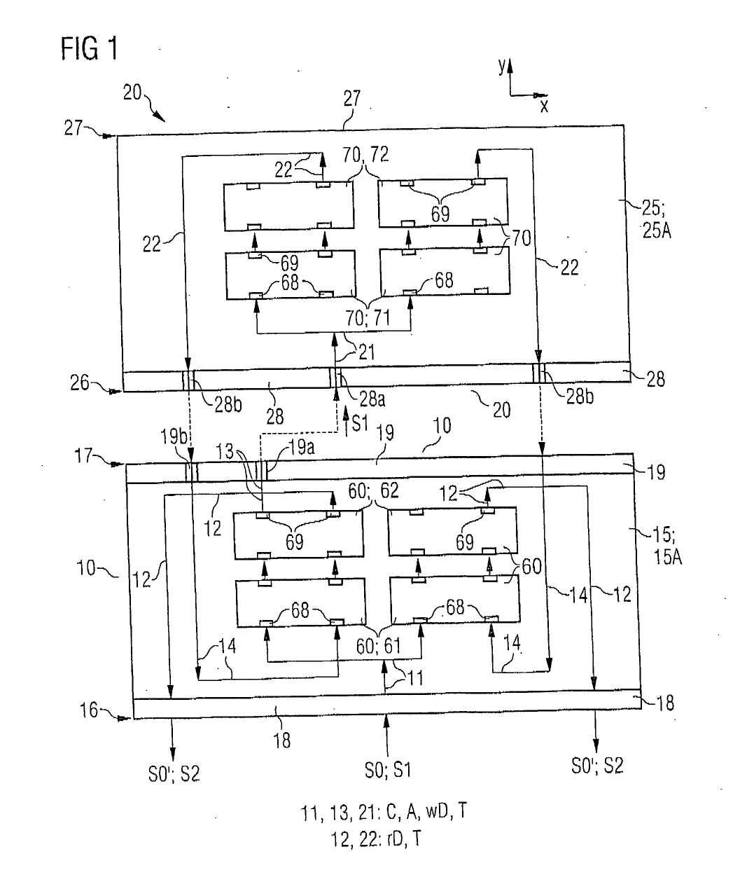

FIG. 1 shows a schematic plan view of a memory module 10 and of a further memory module 20 according to embodiments of the invention. The two memory modules can be connected up to one another. The further memory module 20 can be driven via the memory module 10 to be interposed, without the need for additional contact connections or contact banks for the further memory module 20 on the part of a superordinate electronic unit. Nevertheless, the two memory modules can be operated simultaneously. Furthermore, the memory module 10 can be operated individually or else simultaneously with further memory modules connected downstream of it, for instance the memory module 20. Thirdly, it can also be operated in combination with a conventional memory module that is connected downstream of the memory module 10 instead of the further memory module 20 according to the first embodiment.

FIG. 1 shows the plan view of the memory module 10, the printed circuit board 15 of which has at least one main surface 15A extending along a first direction x and a second direction y. The printed circuit board 15 of the memory module 10 has at a first edge 16 a contact bank 18 having a multiplicity of contact connections that are lined up along the first direction x. According to embodiments of the invention, the memory module 10 has at a second edge 17 a second contact bank 19, the contact connections of which are likewise along this contact bank. Preferably, but not necessarily, the second contact bank can run parallel to the first contact bank and be arranged at the second edge, opposite to the first edge, for instance in the case of a square printed circuit board. The second contact bank provided according to embodiments of the invention serves for data interchange with a further memory module that can be connected indirectly to a superordinate electronic unit via the memory module 10 according to embodiments of the invention. The memory module 10 has first lines 11 that lead proceeding from some connections of the first contact bank 18 at least as far as input connections of some of the semiconductor components 60 which are arranged on the printed circuit board 15. The first lines 11, only a single one of which is illustrated in FIG. 1 (but which represents a plurality of first lines 11), connects all the semiconductor components 60 of a first group of semiconductor components to the first contact bank 18. The first lines 11 are connected in particular to some of the input connections 68 of the semiconductor components 61 of a first group of semiconductor components at which control commands, address commands and data values to be written are preferably received. The precise arrangement and interconnection of the semiconductor components 60, 61 or 62 in FIG. 1 are illustrated merely by way of example and can deviate from FIG. 1.

The memory module 10 furthermore has second lines 12 that reach proceeding from output connections 69 of at least some of the semiconductor components 60, for example the semiconductor components 62, as far as the first contact bank 18. The second lines 12 serve for forwarding data values that have been read out to a superordinate electronic unit.

According to embodiments of the invention, the memory module 10 furthermore has third lines 13 that lead from output connections 69 of at least some of the semiconductor components 60 (for example the semiconductor components which are designated by 62 and belong to a second group of semiconductor components) as far as the second contact bank 19 and are connected there to contact connections 19a of the contact bank. Consequently, the third lines connect some of the output connections 69 of the semiconductor components 62 of the second group to the second contact bank 19 which is provided for the data interchange with a further memory module. The third lines serve, in particular, for transmitting signals S1 intended for the further memory module, in particular control commands, address commands and data values to be stored and also a clock signal communicated in parallel therewith, to the further memory module.

Furthermore, the memory module 10 according to embodiments of the invention likewise has fourth lines 14 that reach proceeding from the second contact bank 19 as far as input connections 68 of at least some of the semiconductor components 60, for example as far as the input connections of the semiconductor components 61 of a first group of semiconductor components. Semiconductor components 61 are connected on the input side to the second contact bank 19 by means of the fourth lines. The contact bank 19 may also be arranged at a further edge adjoining the first edge 16. The arrangement of both contact banks 18 and 19 on opposite edges has the advantage, however, that a further memory module can be connected via its contact bank formed as in a conventional manner to the memory module according to embodiments of the invention with the aid of an adapter or a connecting means.

There are no differences between the semiconductor components 61 of the first group and those semiconductor components 62 of the second group with regard to their construction. The designation of different groups of semiconductor components merely identifies here the semiconductor components to which the first and fourth lines are connected on the input side (namely the semiconductor components 61 of the first group) and the semiconductor components to which the second and third lines are connected on the output side (namely the semiconductor components 62 of the second group). All semiconductor components of one and the same group can be driven in parallel with one another. The semiconductor components of a plurality of groups may optionally be connected in series with one another.

By means of the second contact bank 19 provided according to embodiments of the invention and also the third and fourth lines 13 and 14 that connect the input connections 68 of some semiconductor components 61 and also the output connections 69 of further semiconductor components 62 to the second contact bank 19, a memory module is provided which is not only itself able to be operated with the aid of a superordinate electronic unit, but is also able to be used at the same time as an interface for the data communication with at least one further memory module. As a result, the storage capacity that can be connected to a slot of a superordinate unit, for example a motherboard (that is to say effectively the address space or the total number of memory cells that can be driven directly or indirectly via the memory module) can be doubled or multiplied by connecting one or a plurality of further memory modules to the memory module 10 according to embodiments of the invention with the aid of suitable connecting elements. They can be operated via the memory module 10 according to embodiments of the invention without a dedicated slot of a superordinate electronic unit being required for said further memory modules.

It is preferably provided that the first lines 11 are connected to first input connections 68 of the semiconductor components 60, in particular those semiconductor components 61 of the first group. Furthermore, it is preferably provided that the fourth lines 14 are connected to other, second input connections 68 of the semiconductor components 60, in particular those 61 of the first group of semiconductor components. Furthermore, it is preferably provided that the third lines are connected to first output connections 69 of the semiconductor components 60, in particular those 62 of the second group of semiconductor components. Moreover, it is preferably provided that the second lines are connected to second output connections 69 of the semiconductor components 60, in particular those 62 of the second group of semiconductor components. Those (first) input connections 68 and output connections 69 to which the first and third lines 11 and 13 are connected preferably comprise control lines C, address lines A and lines wD for writing data values to be stored. They may furthermore comprise clock signal lines T. Each of said abovementioned lines may be embodied in the form of one or a plurality of line pairs, two lines biased with complementary signals being provided for each data bit, the potential difference of said lines corresponding to the data bit to be transferred. The second and fourth lines 12 and 14 may preferably comprise data lines rD for data values read out and also further, dedicated clock signal lines T. Accordingly, a multiplicity of lines is represented for each case illustrated in FIG. 1, corresponding to the respectively required number of control lines, address lines, data lines for data to be stored or read-out data of the relevant first, second, third or fourth lines.

The memory module 10 according to embodiments of the invention can be used as an interface for one or a plurality of further memory modules connected downstream. For this purpose, the first lines 11 and also the third lines 13 may also communicate, alongside the signals S0 that drive the memory module 10 according to embodiments of the invention itself, first signals S1 that are intended for further memory modules and drive the latter. Furthermore, the second lines and the fourth lines 12 and 14 may also communicate, alongside the signals S0′ assigned to the memory module 10, second signals S2 assigned to further memory modules connected to a superordinate electronic unit indirectly via the memory module 10.

By way of example, the first and third lines can communicate in cyclic order in each case signals for the semiconductor components 61 of a first group and semiconductor components 62 of a second group of semiconductor components of the memory module 10 and also semiconductor components 71 of a first group and semiconductor components 72 of a second group of semiconductor components of a memory module 20 connected downstream. By virtue of the cyclic order of the communication of data to a plurality of groups (distributed between a plurality of memory modules) of semiconductor components 61, 62, 71 and 72, it is possible for a plurality of memory modules to be driven via the lines of the memory module 10 according to embodiments of the invention. The communication of signals intended for semiconductor components 61, 62, 71 and 72 of a plurality of groups may be effected for example in multiplex operation or demultiplex operation. On the part of a superordinate electronic unit or the memory controller thereof, the data that is transmitted and received back can then be assigned to the respectively correct semiconductor components by means of corresponding data conversion.

The second lines 12 and also the fourth lines 14 of the memory module 10 according to embodiments of the invention can likewise be used for communicating both signals S0′ assigned to the memory module 10 and second signals S2 assigned to a further memory module connected downstream. In this case, too, it is possible to use a suitable multiplex method or demultiplex method in order to communicate data, for example read-out memory data of the memory module 10 and at least one further memory module 20 connected downstream, through the same second and fourth lines. In comparison with the first and third lines 11 and 13, which firstly pass through the semiconductor components of the memory module 10 and only afterward reach semiconductor components of one or a plurality of memory modules connected downstream, with the aid of the second and fourth lines 12 and 14 the read-out data of the memory module 10 and one or a plurality of memory modules connected downstream can be communicated in a temporal order (with regard to the assignment to the respective memory modules) which deviates from that order in which the signals (respectively assigned to the relevant memory modules) are communicated via the first and third lines 11 and 13. The order of the assignment of read-out data values to the respective memory modules will generally be cyclically recurring and periodic. By way of example, given an arrangement of n successively connected memory modules, the first signals can be communicated in cyclic order according to an ascending module number 1, 2, 3, . . . , n, whereas the data values read out are communicated in a different order with regard to the module number of the assigned memory module, for example in the reverse order of descending module number n, . . . , 3, 2, 1. In the case of a deviating order of this assignment in the case of the second signals in comparison with the order of the module assignment in the case of the first signals, a loop back interconnection of the memory modules is achieved. As a result, additional contact connections of the two contact banks of the memory module according to embodiments of the invention are unnecessary for the driving of the memory modules connected downstream.

FIG. 1 additionally shows a further memory module 20 according to embodiments of the invention, which is suitable for being connected via an interposed memory module 10 to a slot of a motherboard or some other superordinate electronic unit. The memory module 20 can thus be driven from the memory module 10 and is connected downstream thereof. In contrast to the memory module 10, the memory module 20 has a contact bank 28 only at a first edge 26 of its printed circuit board 25, the contacts of said contact bank being conductively connected to the semiconductor components of the memory module 20. No such contact bank is provided at the opposite second edge 27. However, at the second edge 27 the printed circuit board 25 of the memory module 20 is formed such that it can be inserted or pushed into a slot of a superordinate electronic unit with the second edge 27, that is to say can be fitted to a corresponding connection device of the superordinate electronic unit. However, only a mechanical fixing and securing is effected, but no electrical contact-making or driving at all. By contrast, the driving is effected via the contact bank 28, that is to say via the contact connections 28a and 28b thereof. The printed circuit board 25 or main surface 25A thereof is formed in the vicinity of the second edge 27 such that the printed circuit board can be pushed, at its second edge, sufficiently deeply into a slot of a superordinate electronic unit. For this purpose, the printed circuit board must be free of relatively large elevations on one or both main surfaces, which elevations do not project further relative to the surface of the printed circuit board than the contact connections 28a and 28b of the contact bank 28. Consequently, relatively large structures on the printed circuit board 25 are set back relative to the second edge 27 in the direction of the contact bank 28.

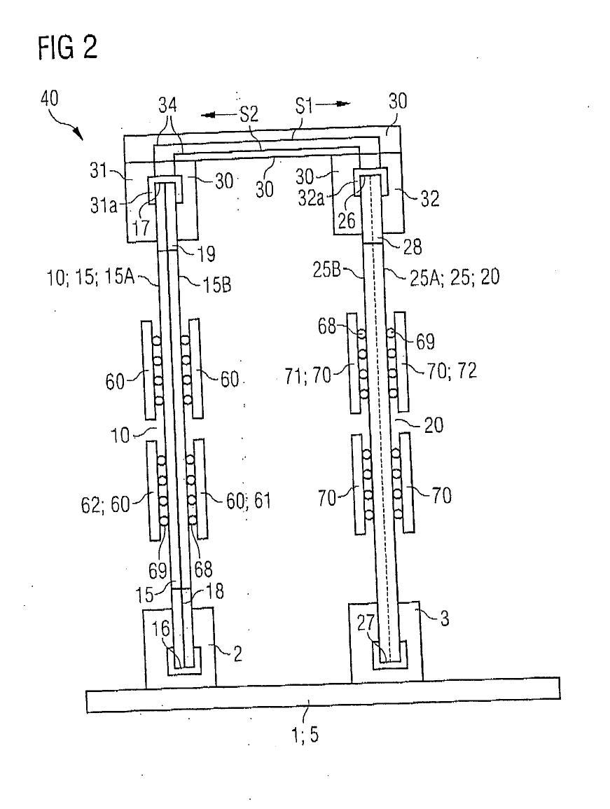

The electrical driving of the further memory module connected downstream of the memory module 10 is effected by means of a suitable connecting means serving as an adapter. The second contact bank 19 of the memory module 10 and also the contact bank 28 of the memory module 20 can be inserted into said connecting means. In this case, as indicated by the dashed line in FIG. 1, the third lines 13 are then conductively connected to first contact connections 28a of the contact bank 28 and the fourth lines of the memory module 10 are conductively connected to second contact connections 28a of the contact bank 28 of the further memory module. As a result, the signals S1 that are intended for the further memory module 20 and are communicated via the first and third lines 11 and 13 of the memory module 10 can be forwarded to the first lines 21 of said further memory module and be communicated from there to the semiconductor components 70 of the further memory module 20. Analogously to the first lines 11 of the memory module 10, signals, in particular preferably control commands, address commands and data values to be stored, are sent through the first lines 21 of the memory module 20 to some of the input connections 68 of semiconductor components 70, in particular semiconductor components 71 of a first group of semiconductor components. Furthermore, analogously to the second lines 12 of the memory module 10, on the memory module 20 second lines 22 are provided that proceed from some further output connections 69 of some semiconductor components 70, in particular those semiconductor components 72 of a second group of semiconductor components, are connected and lead back to the contact bank 28 of the memory module 20. Via the connecting means, which connects both memory modules 10 and 20 to one another and will be explained below with reference to FIG. 2, the second lines 22 of the memory module 20 are connected to the fourth lines of the memory module 10, so that via these and also via the second lines 12 of the first memory module, the read-out data values and also of the memory module 20 connected downstream can be sent in a direction back to a superordinate electronic unit.

In this case, the order of the signals assigned to the respective groups of semiconductor components may be different than for the signals S1 communicated via the lines 11, 13 and 21. While the latter pass in turn through the semiconductor components of the groups 61, 62, 71 and 72, the read-out data values are communicated via the lines 22, 14 and 12 in the order of the semiconductor components of the groups 71, 72, 61 and 62. This order deviates from the order in which the data communicated via the lines 11, 13 and 21 are communicated. The assignment of read-out data values to the semiconductor components 61, 62, 71 and 72 of the correct group of semiconductor components may, however, be effected on the part of the superordinate electronic unit, in the memory controller thereof.

FIG. 2 shows an electronic arrangement having a memory module 10 according to embodiments of the invention and a further memory module 20, which is preferably likewise formed according to embodiments of the invention and which is different from the memory module 10. The arrangement furthermore has a schematically illustrated superordinate electronic unit 1, which may be a motherboard, for example. The electronic unit 1 may have a memory controller (not illustrated), by means of which a plurality of memory modules driven by the electronic unit 1 can be operated. The first memory module 10 formed according to embodiments of the invention in each case has a contact bank 18 and 19 at mutually opposite edges 16 and 17. FIG. 2 illustrates the first memory module 10 and also a further memory module 20 connected downstream in each case in cross-sectional view with respect to the printed circuit board. The memory modules may be populated with semiconductor components 60 and 70, respectively, in each case on one side or on two sides. In addition to the first and second contact banks, the memory module 10 according to embodiments of the invention has the first to fourth lines already described, which are not illustrated diagrammatically in FIG. 2. Via the third and fourth lines and also the second contact bank 19, the memory module 10 enables driving of a further memory module 20 with the aid of a connecting means 30, which connects the second contact bank 19 of the memory module 10 to a contact bank 28 of the further memory module 20 connected downstream. The further memory module 20 can be inserted or pushed into a slot of the superordinate electronic unit 1 in particular upside down, that is to say pivoted through 180° with its second edge 27, at which no conductively interconnected contact bank is formed. As a result, a merely mechanical fixing of the further memory module 20 is achieved, but without the further memory module 20 being driven directly by the superordinate electronic unit 1. Instead, the further memory module 20 receives its electrical signals via the detour of the memory module 10 developed according to embodiments of the invention and the connecting element 30, which is formed as an adapter and which can be plugged or pushed onto both memory modules 10 and 20.

The first memory module 10 developed according to embodiments of the invention has a plurality of semiconductor components 60. Semiconductor components 61 of a first group of semiconductor components can be connected by first input connections to the fourth lines leading to the second contact bank 19. Furthermore, semiconductor components 62 of a second group of semiconductor components can be connected by second output connections 69 to the third lines leading to further contact connections of the second contact bank 19. From the contact bank, the signals are communicated with the aid of the connecting means 30 to the further memory module and in the opposite direction.

The further memory module connected downstream of the memory module 10 and likewise illustrated in FIG. 2 is driven on the part of its single contact bank 28 by the superordinate electronic unit 1 via the first memory module 10. The printed circuit board 25 of the memory module 20 has two main surfaces 25A and 25B, at least one of which is populated with semiconductor components 70. As in the case of the first memory module 10, a plurality of groups 71 and 72 of semiconductor components may also be provided on the memory module 20, in which case, by way of example, semiconductor components 71 of a first group have input connections 68 that are connected to the contact bank 28 by the first lines 21 (FIG. 1). Semiconductor components 72 of a further, second group may likewise have output connections 69 that are connected to further contact connections 28b of the contact bank 28 by second lines 22. No contact bank is provided at the second edge 27 of the memory module 10. Instead, the memory module 20 is formed there in such a way that it can be mechanically fitted to a slot of a superordinate electronic unit 1.

The superordinate electronic unit has a first connection device 2 for the first memory module 10 and also a second connection device 3 for the second memory module 20. Both connection devices 2 and 3 are suitable for directly driving in each case a conventional memory module inserted by its contact bank. On account of the memory module 10 according to embodiments of the invention, it is possible to drive a further memory module 20 which can be mechanically inserted into the connection device 3 without thereby being directly contact-connected.

FIG. 2 furthermore shows a connecting means 30 provided according to embodiments of the invention, which connecting means represents an adapter for electrically interconnecting the two memory modules 10, 20. The connecting means has a first connection device 31 and also a second connection device 32. Each connection device 31 and 32 is formed in such a way that it encloses for example a memory module which is populated with semiconductor components on both sides, and which is formed with a contact bank formed on both sides, in a U-shaped manner from its edge and in this case makes contact with the contacts of the enclosed contact bank. In particular, electrical contacts 31a of the first connection device and also electrical contacts 32a of the second connection device are provided. Furthermore, conductor tracks 34 are provided, which connect the contacts 31a to corresponding contacts 32a in order to forward the first signals S1 in one direction and to forward the second signals S2 in the opposite direction. In particular, with the aid of the connecting means 30, the control commands, address commands and data values to be stored for the second memory module 20 connected downstream are communicated to said memory module and data read out from the memory module 20 are communicated as second signals in the opposite direction to the first memory module 10. The connecting means 30 is preferably formed in such a way that it can be pushed or plugged simultaneously onto both memory modules 10 and 20 in the case of the arrangement illustrated in FIG. 2. As a result, both memory modules 10 and 20 arranged alongside one another can remain inserted in slots of a superordinate electronic unit 1 when the connecting means is removed.

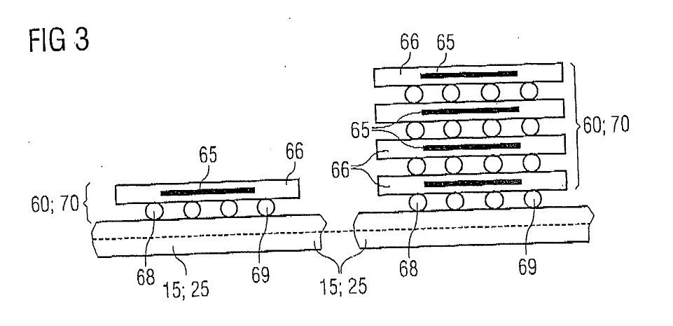

FIG. 3 shows a schematic illustration of a semiconductor component in two different embodiments, which are only by way of example. A semiconductor component 60 is in each case involved which is arranged on the printed circuit board 15 of the first memory module 10 and may optionally have either only one or a plurality, for example four, of housed semiconductor chips stacked one above another. As an alternative, a semiconductor component 70 is involved which is arranged on the printed circuit board 25 of the second memory module 20 and may likewise have one or a plurality of housed semiconductor chips (or else unhoused semiconductor chips). If the semiconductor components comprise housed semiconductor chips, each semiconductor chip 65 is surrounded by a corresponding chip housing 66 that is preferably formed as a BGA (ball grid array). Some of the contact connections are schematically designated as input connections 68 and some other contact connections are schematically designated as output connections 69, in order to indicate the contact connections to which the first and second lines of the relevant memory module 10 and 20 can be connected or the third and fourth lines of the memory module 10 can be connected. At least some input-side and output-side contact connections of a chip housing 66 mounted directly at the printed circuit board 15 or 25 or of a semiconductor chip mounted in unhoused fashion are connected to the first to fourth lines. In each of the memory modules, the respective semiconductor component 60 or 70 may optionally comprise only one or a plurality of housed or unhoused semiconductor chips. With regard to the arrangement comprising two memory modules 10 and 20 as illustrated in FIG. 3, the semiconductor components 60 and 70 of a respective memory module may, in groups, either be connected in series with one another or be connected in parallel with one another. The first or second signals assigned to the semiconductor components of the different groups may, in the same way as the signals assigned to the different groups of the semiconductor components, be communicated successively along the first to fourth lines, for example in cyclic order of the respective groups of semiconductor components of the respective memory module, each cycle being interrupted by signals which are assigned to the respective groups of semiconductor components of the respective other memory module 20 and 10.

The first to fourth lines may in each case contain byte lanes, which, by way of example, in the case of the first and third lines, comprise six double lines for six data bits and one double line for a clock signal and, in the case of the second and fourth lines, comprise four double lines plus one double line for a further clock signal. With the aid of the memory modules 10 and 20 according to embodiments of the invention, these memory modules can be connected up to one another in the form of a loop back configuration.

Independently of the arrangement and interconnection of the individual semiconductor components on the memory modules, embodiments of the present invention enable the utilization of slots already present on a motherboard or on some other electronic unit for memory modules more flexibly than is conventional and the operation of a plurality of memory modules with a larger storage capacity and/or number than conventionally possible on the part of the motherboard or a corresponding other superordinate electronic unit, in particular its memory controller.

What is claimed is:

1. A memory module comprising:
an electronic printed circuit board;
a plurality of semiconductor components;
wherein the printed circuit board has at least one main surface and also at least one first edge and one second edge;
wherein the semiconductor components are arranged on the at least one main surface of the printed circuit board;
wherein the printed circuit board has on the at least one main surface a first contact bank, that is arranged at the first edge of the printed circuit board, and also a second contact bank, that is arranged at the second edge of the printed circuit board, wherein the first and second contact banks each have a multiplicity of contact connections;
wherein the printed circuit board has first lines that extend from the first contact bank to input connections of at least some of the semiconductor components;
wherein the printed circuit board has second lines that extend from output connections of at least some of the semiconductor components to the first contact bank;
wherein the printed circuit board has third lines that extend from output connections of at least some of the semiconductor components to the second contact bank; and
wherein the printed circuit board has fourth lines that extend from the second contact bank as far as input connections of at least some of the semiconductor components.

2. The memory module as claimed in claim 1, wherein the plurality of the semiconductor components includes a first group of semiconductor components and a second group of semiconductor components, wherein the first and the fourth conductor lines are coupled to input connections of the semiconductor components of the first group, and wherein the second and third conductor lines are coupled to output connections of the semiconductor components of the second group.

3. The memory module as claimed in claim 2, wherein at least some of the semiconductor components of the first group are driven in parallel with one another, wherein at least some of the semiconductor components of the second group are driven in parallel with one another, and wherein the semiconductor components of the first group are coupled in series with the semiconductor components of the second group.

4. The memory module as claimed in claim 3, wherein the semiconductor components of the first group are coupled in series with the semiconductor components of the second group in such a way that at least some electrical signals that are communicated by the first and/or fourth conductor lines to the semiconductor components of the first group are forwarded through the semiconductor components of the first group at least to the semiconductor components of the second group.

5. The memory module as claimed in claim 4, wherein the semiconductor components of the first group are coupled in series with semiconductor components of the second group in such a way that electrical signals that are conducted from output connections of the semiconductor components of the first group to semiconductor components of the second group are forwarded through the semiconductor components of the second group as far as the second and/or third conductor lines.

6. The memory module as claimed in claim 1, wherein the memory module can be connected directly to a superordinate electronic unit by means of the first contact bank and can be connected up to at least one further memory module by means of the second contact bank in such a way that the at least one further memory module is driven via the memory module connected directly to the superordinate electronic unit.

7. The memory module as claimed in claim 1, wherein the third conductor lines of the printed circuit board of the memory module lead to contacts of the second contact bank that are intended for forwarding signals to at least one further memory module.

8. The memory module as claimed in claim 1, wherein the fourth conductor lines of the memory module are coupled to contact connections of the second contact bank that are intended for receiving signals from at least one further memory module.

9. The memory module as claimed claim 1, wherein the second conductor lines forward to the first contact bank both signals read out from the semiconductor components of the memory module and those signals which are received with the aid of the second contact bank and forwarded through the fourth lines and the semiconductor components.

10. The memory module as claimed in claim 1, wherein the first lines forward both signals intended for processing in the semiconductor components of the memory module and signals that are to be forwarded as far as the second contact bank, wherein the signals that are to be forwarded as far as the second contact bank are forwarded to contact connections of the second contact bank via the semiconductor components of the memory module and via the third conductor lines.

11. The memory module as claimed in claim 1, wherein the third conductor lines comprise control lines, address lines and data lines for data to be written to the semiconductor components.

12. The memory module as claimed in claims 11, wherein the fourth conductor lines comprise data lines for data to be read out.

13. The memory module as claimed in claim 12, wherein the third and the fourth conductor lines each further comprise clock signal lines that communicate a clock signal.

14. The memory module as claimed in claim 1, wherein the first and the second edge run along a first direction, and wherein the at least one main surface extends between the first and the second edge.

15. A memory module comprising:
an electronic printed circuit board; and
a plurality of semiconductor components;
wherein the printed circuit board has at least one main surface and also a first edge and a second edge, wherein the first edge and the second edge run along a first direction, and wherein the at least one main surface extends between the first and the second edge; and
wherein the printed circuit board can be mounted both at the first edge and at the second edge at a superordinate electronic unit, and wherein the printed circuit board has a contact bank at the first edge.

16. The memory module as claimed in claim 15, wherein the memory module can be mounted at its second edge at the superordinate electronic unit without the memory module being drivable from its second edge directly by the superordinate electronic unit.

17. The memory module as claimed in claim 15, wherein the memory module is constituted such that it can be driven via the contact bank from its first edge of the printed circuit board optionally either directly by a superordinate electronic unit, or can be driven via another memory module.

18. The memory module as claimed in claim 17, wherein the memory module can be driven via the contact bank at the first edge of the printed circuit board optionally either directly by the superordinate electronic unit or by a memory module.

19. The memory module as claimed in claim 15, wherein the memory module has a contact bank only at its first edge, and wherein first and second lines are coupled to contact connections of the contact bank;
wherein the first lines extend from contacts of the contact bank to input connections of at least some of the semiconductor components; and
wherein the second lines extend from output connections of at least some further semiconductor components to further contacts of the contact bank.

20. The memory module as claimed in claim 15, wherein the printed circuit board has two main surfaces that are remote from one another and that are both populated with semiconductor components.

21. The memory module as claimed in claim 20, wherein each contact bank of the printed circuit board has a plurality of contact connections on both main surfaces of the printed circuit board.

22. The memory module as claimed in claim 15, wherein first lines that extend from the contact strip to input connections of the semiconductor components comprise control lines, address lines and data lines for data to be written to the semiconductor components.

23. The memory module as claimed in claim 22, wherein second lines that extend from the contact strip to output connections of the semiconductor components comprise data lines for data to be read out from the semiconductor components.

24. The memory module as claimed in claim 23, wherein the first and the second lines each further comprise clock signal lines that communicate a clock signal.

25. The memory module as claimed in claim 22, wherein the first lines have branching nodes at which the first lines branch toward a plurality of semiconductor components of the memory module that are to be driven in parallel with one another.

26. The memory module as claimed in claim 25, wherein, proceeding from the branching nodes, the first lines lead to the semiconductor components of a first group of semiconductor components.

27. The memory module as claimed in claim 15, wherein the semiconductor components each comprise a housed semiconductor chip whose chip housing has input connections and output connections mounted at the printed circuit board.

28. The memory module as claimed in claim 27, wherein the semiconductor components in each have a plurality of housed semiconductor chips that are stacked one above another and a bottommost housed semiconductor chip of which in each case is mounted at the printed circuit board.

29. The memory module as claimed in claim 27, wherein the semiconductor chips comprise dynamic read/write memories.

30. The memory module as claimed in claim 15, wherein the memory module has at least two groups of semiconductor components, wherein each group of semiconductor components comprises a plurality of semiconductor components driven in parallel with one another, and wherein the semiconductor components of one group are in each case connected in series with the semiconductor components of the other group.

31. A connecting apparatus for electrically connecting two memory modules to one another, the connecting apparatus comprising:
a first connection device to which a memory module can be directly connected; and
a second connection device, to which a memory module can be connected directly, wherein the first connection device and the second connection device each has a multiplicity of electrical contacts, and wherein a plurality of contacts of the first connection device are coupled to a plurality of contacts of the second connection device.

32. The connecting apparatus as claimed in claim 31, wherein the first connection device and the second connection device are constituted such that an electronic printed circuit board of a memory module can in each case be inserted or plugged into the respective connection device.

33. The connecting apparatus as claimed in claim 31, wherein the first and the second connection device are constituted such that a printed circuit board of a memory module which has a contact bank with a multiplicity of electrical contact connections at an edge can in each case be connected to the respective connection device in such a way that the contact connections of the contact bank of the printed circuit board make contact with the electrical contacts of the respective connection device of the connecting apparatus.

34. The connecting apparatus as claimed in claim 34, wherein the first and the second connection device are oriented such that the connecting apparatus can be simultaneously pushed or plugged onto two memory modules, each memory module having a printed circuit board that faces the connecting apparatus with an edge.

35. An electronic arrangement comprising:
at least one first memory;
at least one second memory module;
a connecting apparatus;
a superordinate electronic unit, by which the first and second memory modules are driven;
wherein the superordinate electronic unit has a first and a second connection device, at which one of the memory modules can in each case be mounted;
wherein the first memory module is mounted with its first edge at the first connection device of the superordinate electronic unit and with its second edge at the first connection device of the connecting apparatus; and
wherein the second memory module is mounted with its first edge at the second connection device of the connecting apparatus and with its second edge at the second connection device of the superordinate electronic unit.

36. The arrangement as claimed in claim 35, wherein the first memory module is electronically driven by the first connection device of the superordinate electronic unit, and wherein the second memory module is mechanically fixed with its second edge at the second connection device without being electrically driven by the superordinate electronic unit via the second connection device.

37. The arrangement as claimed in claim 35, wherein the second memory module is electrically driven by the superordinate electronic unit via the first memory module and the connecting apparatus.

38. The arrangement as claimed in claim 35, wherein at least the second connection device of the connecting apparatus and the first and the second connection device of the superordinate electronic unit are formed in the same way, with the result that the second memory module can optionally be connected to one of said three connection devices with its contact bank arranged at the first edge.

39. The arrangement as claimed in claim 35, wherein the superordinate electronic unit has a main circuit board, wherein a plurality of memory modules can be fitted to the main circuit board and can be electrically driven via the main circuit board.

40. The arrangement as claimed in claim 35, wherein the connecting apparatus connects the third lines of the first memory module to first lines of the second memory module and connects fourth lines of the first memory module to the second lines of the second memory module.

41. A method for operating at least one first and one second memory module, wherein the first and the second memory module each have an electronic printed circuit board and a plurality of semiconductor components, and wherein the printed circuit board of the first and of the second memory module in each case have first and second lines, the method comprising:
connecting the first lines to input connections of at least some of the semiconductor components, and wherein the second lines are connected to output connections of at least some of the semiconductor components; and
operating the first and the second memory module in such a way that clock signals and other first signals are forwarded via the first lines and via the semiconductor components of the first memory module to the second memory module and are processed in the second memory module.

42. The method as claimed in claim 41, wherein the first signals are forwarded to the second memory module via interposed third lines of the first memory module, which are connected to output connections of at least some of the semiconductor components of the first memory module.

43. The method as claimed in claim 41, wherein the first and the second memory modules are operated in such a way that clock signals and also other second signals are furthermore forwarded via the second lines of the second memory module to the first memory module.

44. The method as claimed in claim 43, wherein the second signals are forwarded in the first memory module via the semiconductor components of the first memory module to the second lines of the first memory module.

45. The method as claimed in claim 43, wherein the second lines are forwarded via interposed fourth lines of the first memory module, which are connected to input connections of at least some of the semiconductor components of the first memory module, within the first memory module as far as the semiconductor components thereof.

46. The method as claimed in claim 41, wherein both signals that drive the first memory module and first signals that drive the second memory module are forwarded via the first lines of the first memory module.

47. The method as claimed in claim 41, wherein both signals that are assigned to the first memory module and the second signals that are assigned to the second memory module are forwarded via the second lines of the first memory module.

48. The method as claimed in claim 42, wherein the first signals comprise control commands, address commands and data to be stored.

49. The method as claimed in claim 44, wherein the second signals comprise data to be read out.

50. The method as claimed in claim 41, wherein the second memory module is electrically driven via the first memory module.
